(19) United States
(12) Patent Application Publication
(10) Pub. No.: US 2026/0253455 A1
(43) Pub. Date: Aug. 27, 2026

(54) INFORMATION PROCESSING APPARATUS, INFORMATION PROCESSING METHOD, AND NON-TRANSITORY COMPUTER READABLE MEDIUM

(71) Applicant: NEC Corporation, Tokyo (JP)

(72) Inventors: Norihito OI, Tokyo (JP); Kouki OOURA, Tokyo (JP); Tooru IWAMOTO, Tokyo (JP); Tatsuya OSADA, Tokyo (JP)

(73) Assignee: NEC Corporation, Tokyo (JP)

(21) Appl. No.: 19/489,739

(22) PCT Filed: Jun. 28, 2023
(86) PCT No.: PCT/JP2023/024059

§ 371 Date: Dec. 3, 2025

(51) Int. Cl. G07C 5/00; B60L 58/12; G06F 30/20; G06T 11/65

(52) U.S. Cl. CPC G07C 5/004; B60L 58/12; G06F 30/20; G06T 11/65

(57) ABSTRACT

An information processing device (100) is provided with a simulation unit (103) and a range estimation unit (104). The simulation unit (103) uses actual travel data of a first vehicle, which uses fuel as the energy source thereof, associated with the target base, to perform a simulation pertaining to the power to be consumed when a second vehicle, which uses electricity as the energy source thereof, travels in accordance with the actual travel data. The range estimation unit (104) uses the result of the simulation to estimate a travelable range in accordance with a plurality of stage-specific criteria pertaining to the power shortage risk.

### TECHNICAL FIELD

The present invention relates to an information processing apparatus, an information processing method, and a recording medium.

### BACKGROUND ART

PTL 1 describes an operation plan creation support device that predicts actual operation for a given provisional schedule from predicted values of a travel time predicted value, an electricity consumption predicted value, and a charging time predicted value.

### CITATION LIST

### Patent Literature

PTL 1: JP 2015-138501 A

### SUMMARY OF INVENTION

### Technical Problem

However, even if operation is performed according to the provisional schedule, it may be difficult to actually operate according to the provisional schedule. There is a problem that the accuracy of each predicted value described in PTL 1 decreases in a case where the train cannot actually operate according to the provisional schedule.

In view of the above-described problem, an object of the present invention is to provide an information processing device, an information processing method, a recording medium, and the like that enable accurate estimation of a travelable range of an automobile using electricity as an energy source.

### Solution to Problem

One aspect of the present invention provides an information processing device including
a simulation means for using actual travel data of a first automobile using fuel as an energy source to perform a simulation regarding electricity consumed in a case where a second automobile using electricity as an energy source travels according to the actual travel data, the actual travel data being associated with a target facility, and
a range estimation means for estimating a travelable range according to a plurality of stepwise criteria regarding a battery depletion risk using a result of the simulation.

One aspect of the present invention provides an information processing method including
one or more computers
using actual travel data of a first automobile using fuel as an energy source to perform a simulation regarding electricity consumed in a case where a second automobile using electricity as an energy source travels according to the actual travel data, the actual travel data being associated with a target facility, and
estimating a travelable range according to a plurality of stepwise criteria regarding a battery depletion risk using a result of the simulation.

One aspect of the present invention provides a recording medium recording a program for causing one or more computers to
use actual travel data of a first automobile using fuel as an energy source to perform a simulation regarding electricity consumed in a case where a second automobile using electricity as an energy source travels according to the actual travel data, the actual travel data being associated with a target facility, and
estimate a travelable range according to a plurality of stepwise criteria regarding a battery depletion risk using a result of the simulation.

### Advantageous Effects of Invention

According to one aspect of the present invention, it is possible to accurately estimate a travelable range of an automobile using electricity as an energy source.

### BRIEF DESCRIPTION OF DRAWINGS

FIG. 1 It is a diagram illustrating an outline of an information processing device according to the present disclosure.

FIG. 2 It is a flowchart illustrating an outline of information processing according to the present disclosure.

FIG. 3 It is a diagram illustrating a functional configuration of the information processing device according to the present disclosure.

FIG. 4 It is a diagram illustrating an example of a physical configuration of the information processing device according to the present disclosure.

FIG. 5 It is a flowchart illustrating an example of information processing according to the present disclosure.

FIG. 6 It is a diagram illustrating a display example of a travelable range according to a stepwise criterion in which a ratio of a remaining capacity is 50%.

FIG. 7 It is a diagram illustrating a display example of a travelable range according to a stepwise criterion in which a ratio of a remaining capacity is 27.5%.

FIG. 8 It is a diagram illustrating a display example of a travelable range according to a stepwise criterion in which a ratio of a remaining capacity is 20%.

FIG. 9 It is a diagram illustrating a display example of a travelable range according to a plurality of stepwise criteria.

FIG. 10 It is a diagram illustrating a display example of a plurality of assigned regions.

### EXAMPLE EMBODIMENT

Hereinafter, example embodiments of the present invention will be described with reference to the drawings. In all the drawings, the same components are denoted by the same reference numerals, and the description thereof will be omitted as appropriate. In the present disclosure, the drawings are associated with one or more example embodiments.

### Outline

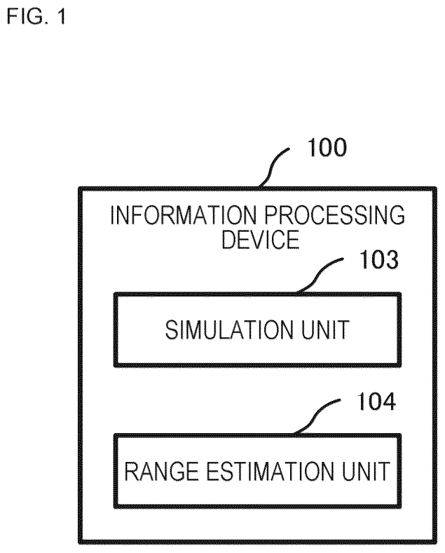

An information processing device 100 according to the present disclosure includes a simulation unit 103 and a range estimation unit 104 as an outline thereof is illustrated in FIG. 1.

The simulation unit 103 uses actual travel data of a first automobile using fuel as an energy source, which is associated with a target facility, to perform a simulation regarding electricity consumed in a case where a second automobile using electricity as an energy source travels according to the actual travel data.

Using the result of the simulation, the range estimation unit 104 estimates a travelable range according to a plurality of stepwise criteria regarding a battery depletion risk.

According to the information processing device 100, it is possible to accurately estimate a travelable range of an automobile using electricity as an energy source.

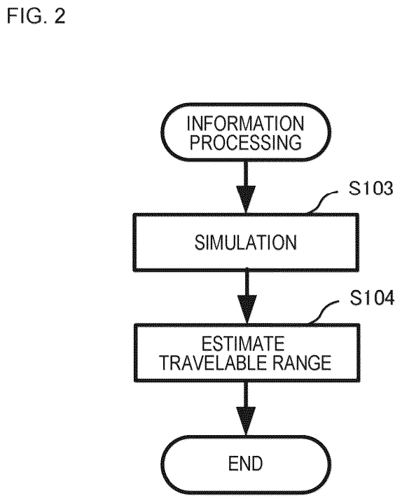

The information processing according to the present disclosure generally includes processing illustrated in a flowchart of FIG. 2.

The simulation unit 103 uses actual travel data of the first automobile using fuel as an energy source, which is associated with a target facility, to perform a simulation regarding electricity consumed in a case where the second automobile using electricity as an energy source travels according to the actual travel data (step S103).

Using the result of the simulation, the range estimation unit 104 estimates a travelable range according to a plurality of stepwise criteria regarding the battery depletion risk (step S104).

According to this information processing, it is possible to accurately estimate a travelable range of an automobile using electricity as an energy source.

Hereinafter, detailed examples of the information processing device 100, the information processing, and the like according to the present disclosure will be described.

### First Example Embodiment

The information processing device 100 according to the present disclosure is a device that estimates a relationship between a battery depletion risk and a travelable range of a second automobile in a case where the second automobile is used instead of a first automobile associated with a target facility.

The first automobile is an automobile used for business execution, and is an automobile using fuel as an energy source. The fuel is, for example, fossil fuel, and is diesel oil, gasoline, liquefied petroleum gas (LPG), or the like. The fuel is not limited to those exemplified here.

The second automobile is an automobile used instead of the first automobile for business execution, and is an automobile using electricity as an energy source. The second automobile is, for example, an electric automobile, a fuel cell vehicle, a hybrid car, or the like.

In a case where the second automobile is used instead of the first automobile, it is desirable to be able to grasp in advance a range in which the second automobile can travel without running out of electricity (running out of power of rechargeable battery loaded on second automobile). Therefore, the information processing device 100 estimates the relationship between the battery depletion risk and the travelable range of the second automobile in a case where the second automobile is used instead of the first automobile associated with the target facility.

The business using the first automobile is, for example, a transportation business such as home delivery, a moving business of carrying goods to a moving destination, and the like. The business may be any business that uses automobiles for business execution, and is not limited to the businesses exemplified here.

The target facility is a place where an automobile is stored, a place where at least one of fuel and electricity is supplied to the automobile, a place where packages such as home delivery are collected and delivered, and the like. The target facility is associated with the first automobile, for example, as a place where the first automobile is stored or refueled, and packages are collected or delivered.

Examples of the target facility are not limited to those exemplified here. The mode in which the target facility and the first automobile are associated with each other is not limited to the mode exemplified here.

### Functional Configuration Example of Information Processing Device 100

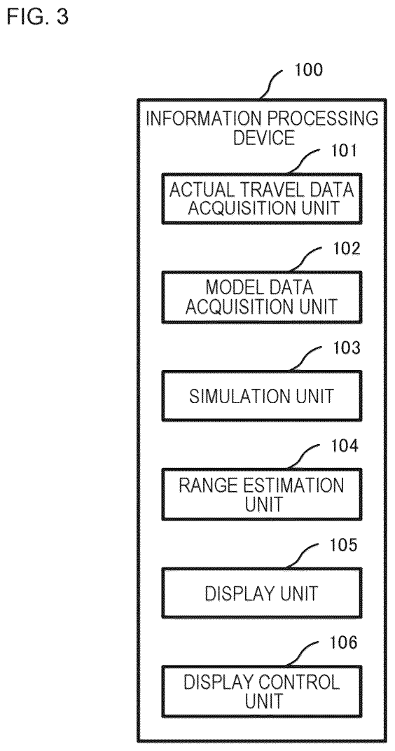

As illustrated in FIG. 3 as an example of a functional configuration, the information processing device 100 functionally includes, for example, an actual travel data acquisition unit 101, a model data acquisition unit 102, the simulation unit 103, the range estimation unit 104, a display unit 105, and a display control unit 106.

The actual travel data acquisition unit 101 acquires at least one piece of actual travel data.

The actual travel data is data related to the travel of the first automobile that has actually traveled for business execution.

For example, the actual travel data may include information regarding the target business, the vehicle, and the driver.

The information regarding the target business may include, for example, a type of the target business such as moving and delivery. The information regarding the target business is not limited thereto.

The information regarding the vehicle may include, for example, a vehicle type. The information regarding the vehicle is not limited thereto, and may include, for example, at least one of vehicle weight, acceleration resistance, air resistance, rolling resistance, gradient resistance, or parameters related thereto. The information regarding the vehicle may include, for example, at least one of a vehicle class and the availability and usage status of regenerative energy.

The information regarding the driver is preferably information related to the driving skill of the driver, and may be, for example, one of the experience period of the target business, the number of executions of the target business, the age, the number of years of driving experience of an automobile, and the like. The information regarding the driver is not limited thereto, and may include at least one of information regarding driving characteristics (timing of stepping on brake, degree of acceleration, and the like) of the driver, information regarding a break time of the driver, information regarding a waiting time of the driver, and the like.

For example, the actual travel data may include travel history information that can change over time according to the actual travel, road condition information indicating the condition of the road on which the first automobile has traveled, and the like.

The travel history information may include, for example, at least one of a loading amount of cargo, a refueling amount at the start of travel, a travel distance and a fuel consumption amount (or remaining amount of fuel), a travel position, a travel speed, an acceleration/deceleration state of the speed, a stop state, and the like.

The travel history information may be acquired from, for example, a driving recording device for acquiring and recording travel history information mounted on the first automobile that actually travels. The method for acquiring the travel history information is not limited thereto.

The road condition information may include, for example, at least one of a road gradient of a traveling place, a congestion situation of a road, and the like.

For example, the road condition information may be acquired from a sensor mounted on the first automobile traveling at the time, recorded in the above-described driving recording device or the like, and acquired from the driving recording device. For example, the road condition information may be acquired from an external device that provides general road conditions. The method for acquiring the road condition information is not limited thereto.

The information included in the actual travel data, the travel history information, and the road condition information is not limited to those exemplified here. The actual travel data may include at least one type of the information and the like exemplified here.

The model data acquisition unit 102 acquires model data.

The model data is data serving as a model relating to electricity consumed by the second automobile in association with traveling.

For example, the model data may include electricity cost information, that is, information indicating a travel distance per unit power consumption. For example, the model data may include information similar to the information included in the actual travel data described above.

The information included in the model data is not limited to the information exemplified here. The model data may include at least one type of the information and the like exemplified here.

The model data may be created in advance based on, for example, experimental traveling of the second automobile. In a case where a plurality of experimental travels are performed, an average value or the like of values obtained by the experimental travels may be adopted as the model data. For example, the model data acquisition unit 102 may acquire the model data from a device that holds such model data created by experimental traveling.

The method of creating the road condition information and the method of acquiring the model data by the model data acquisition unit 102 are not limited thereto.

Using the actual travel data acquired by the actual travel data acquisition unit 101, the simulation unit 103 performs a simulation regarding electricity consumed in a case where the second automobile travels according to the actual travel data.

For example, the simulation unit 103 may perform a simulation by further using the model data acquired by the model data acquisition unit 102. That is, the simulation may be performed by further using model data related to electricity consumed by the second automobile in association with traveling.

The result of the simulation may include at least one of electricity cost information, power consumption, and the like in a case where the second automobile travels according to the actual travel data. The simulation condition may be set as appropriate. For example, the initial condition (condition at start of traveling in simulation) related to the state of charge (SOC) of the second automobile may be the full charge, or an appropriate value such as a ratio to the full charge may be set.

Using the result of the simulation performed by the simulation unit 103, the range estimation unit 104 estimates a travelable range according to a plurality of stepwise criteria regarding the battery depletion risk.

The plurality of stepwise criteria regarding the battery depletion risk may be determined using, for example, a ratio of a remaining capacity to a full charge, a remaining capacity, and the like. Specifically, for example, in a case where the ratio of the total capacity to the full charge is adopted, the plurality of stepwise criteria are two or more, such as 50%, 27.5%, and 20%. The plurality of stepwise criteria may be appropriately determined with respect to the battery depletion risk, and are not limited to those exemplified here.

The display unit 105 displays various types of information. The display control unit 106 causes the display unit 105 to display various types of information.

For example, the display control unit 106 causes the display unit 105 to display a map.

For example, the display control unit 106 causes the display unit 105 to display a travelable range according to at least one stepwise criterion on the map displayed on the display unit 105. The display mode of the travelable range may be different for each stepwise criterion. The display mode may include, for example, one or more of color, thickness, line type, and the like. It is only necessary to provide one or more stepwise criteria.

For example, the display control unit 106 may further cause the display unit 105 to display an assigned region determined in advance for the target facility on the map displayed on the display unit 105. That is, a predetermined assigned region for the target facility may be further displayed on the map displayed on the display unit 105.

The display control unit 106 may cause the display unit 105 to display a non-assigned region in a mode different from the assigned region. The non-assigned region is a region other than the assigned region. In other words, the non-assigned region is a region not included in the assigned region.

### Exemplary Physical Configuration of Information Processing Device 100

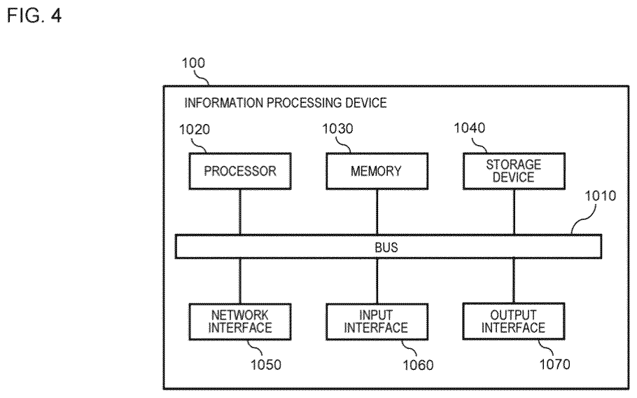

Physically, for example, as illustrated in FIG. 4, the information processing device 100 includes a bus 1010, a processor 1020, a memory 1030, a storage device 1040, a network interface 1050, an input interface 1060, and an output interface 1070.

The bus 1010 is a data transmission path through which the processor 1020, the memory 1030, the storage device 1040, the network interface 1050, the input interface 1060, and the output interface 1070 mutually transmit and receive data. Note, however, that the method for connecting the processor 1020 and other components to each other is not limited to the bus connection.

The processor 1020 is a processor implemented by a central processing unit (CPU), a graphics processing unit (GPU), or the like.

The memory 1030 is a main storage device implemented by a random access memory (RAM) or the like.

The storage device 1040 is an auxiliary storage device implemented by a hard disk drive (HDD), a solid state drive (SSD), a memory card, a read only memory (ROM), or the like. The storage device 1040 stores program modules for implementing functions of an apparatus including the storage device 1040. The processor 1020 reads these program modules into the memory 1030 to execute them, thereby implementing the functions associated with the program modules.

The network interface 1050 is an interface for connecting the device including this network interface 1050 to a network N.

The input interface 1060 is an interface for the user to input information. The input interface 1060 includes, for example, a touch panel, a keyboard, a mouse, and the like.

The output interface 1070 is an interface for presenting information to the user. The output interface 1070 includes, for example, a liquid crystal panel, an organic electro-luminescence (EL) panel, or the like.

Although the example in which the information processing device 100 is physically configured by a single apparatus has been described, it may be physically configured by a plurality of apparatuses. In this case, each of the plurality of apparatuses may be physically configured similarly to the information processing device 100.

### Operation Example of Information Processing Device 100 According to First Example Embodiment

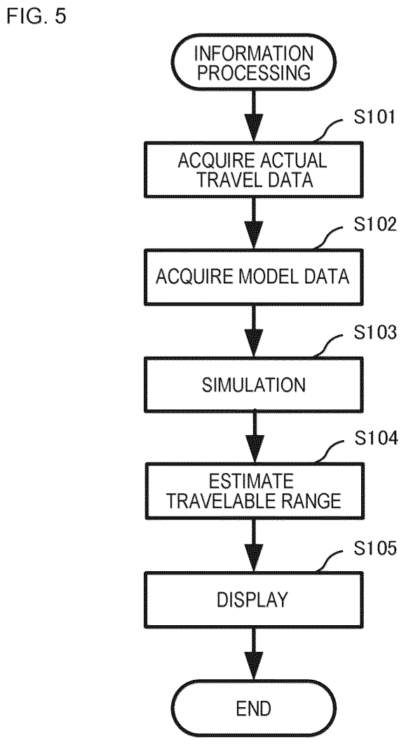

Hereinafter, an example of the information processing according to the present disclosure will be described with reference to FIG. 5.

The information processing is processing for estimating the relationship between the battery depletion risk and the travelable range of the second automobile in a case where the second automobile is used instead of the first automobile associated with the target facility. The information processing may be started, for example, in response to an instruction from the user. The trigger for starting the information processing is not limited thereto.

The actual travel data acquisition unit 101 acquires actual travel data (step S101).

For example, the actual travel data is data related to travel of the first automobile in a case where the first automobile selected as appropriate actually travels during a predetermined period (e.g., one day) during work. For example, the actual travel data acquisition unit 101 may acquire a plurality of pieces of actual travel data related to the same first automobile associated with the same target facility. A method of selecting the plurality of pieces of actual travel data is, for example, a period between specified dates (e.g., one month), but is not limited thereto, and an appropriate method may be adopted.

The model data acquisition unit 102 acquires model data (step S102).

Using the actual travel data acquired in step S101, the simulation unit 103 performs a simulation regarding electricity consumed in a case where the second automobile travels according to the actual travel data (step S103).

For example, the simulation unit 103 performs a simulation by further using the model data acquired in step S102.

Specifically, for example, the simulation unit 103 uses the actual travel data and the model data to generate electricity cost information in a case where the second automobile travels according to the actual travel data.

More specifically, for example, it is assumed that the actual travel data includes information regarding the target business, the vehicle, and the driver, travel history information, and road condition information.

In this case, it is possible to obtain the result of the simulation in a case where the second automobile is used to travel for a target business similar to the target business included in the actual travel data.

For example, it is possible to obtain the result of the simulation in a case where the second automobile is used to travel under a condition corresponding to the vehicle included in the actual travel data. The condition corresponding to the vehicle is, for example, a condition related to vehicle weight. The condition in this case is, for example, a condition that the second automobile has the same vehicle weight as the vehicle weight identified by the vehicle type.

For example, it is possible to obtain the result of the simulation in a case where the second automobile is used to travel under a condition corresponding to the information regarding the driver included in the actual traveling data. The condition corresponding to the information regarding the driver is, for example, a condition regarding a driving skill. The driving skill is represented by, for example, a value obtained according to a predetermined calculation formula, a matrix, or the like based on an experience period or the like included in the information regarding the driver. The condition in this case is, for example, a condition that the second automobile is driven with the same driving skill as a driving skill identified by the information regarding the driver.

For example, it is possible to obtain the result of the simulation in a case where the second automobile is used to travel under the condition of traveling in a manner similar to the travel history information included in the actual travel data. For example, it is possible to obtain the result of the simulation in a case where the second automobile is used to travel under the condition of traveling in a road condition similar to that in the road condition information included in the actual travel data.

For example, if a plurality of pieces of actual travel data are acquired in step S101, the simulation unit 103 may perform a simulation regarding electricity consumed in a case where the second automobile travels according to each of the plurality of pieces of actual travel data. The simulation method is not limited to the method described here.

Using the result of the simulation performed in step S103, the range estimation unit 104 estimates a travelable range according to a plurality of stepwise criteria regarding a battery depletion risk (step S104).

For example, if the simulation is performed according to each of the plurality of pieces of actual travel data in step S103, the range estimation unit 104 may estimate the travelable range according to the plurality of stepwise criteria using each of the results of the plurality of simulations. In the estimation of the travelable range, for example, at least one of topography such as a road gradient, a road width, travel restrictions such as speed and construction, and the like may be used. For example, in the estimation of the travelable range, at least one of a business area, an economic area prepared in advance using a game theory, or the like may be used.

The display control unit 106 causes the display unit 105 to display a travelable range according to at least one stepwise criterion on a map displayed on the display unit 105 (step S105).

If the travelable range is estimated using each of a plurality of simulation results in step S104, the display control unit 106 may cause the display unit 105 to display the estimation results of the travelable range on the display unit 105 in one screen.

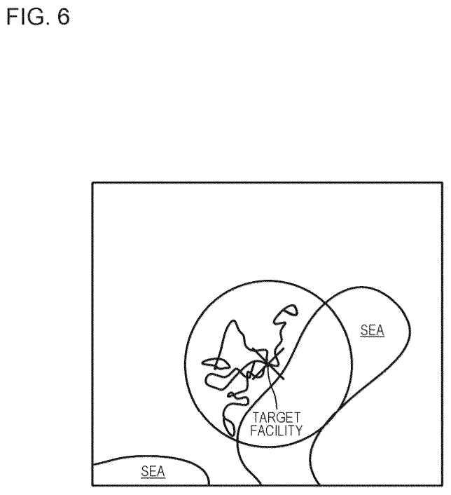

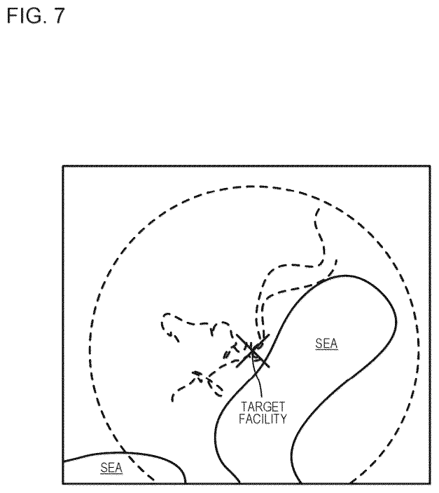

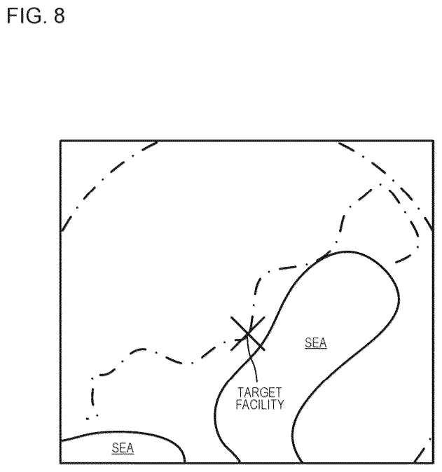

Each of FIGS. 6 to 8 is a diagram illustrating a display example of a travelable range according to one stepwise criterion. Specifically, FIGS. 6 to 8 are diagrams illustrating a display example of the travelable range according to the stepwise criteria in which the ratios of the remaining capacities are 50%, 27.5%, and 20%, respectively. In each diagram, the travelable range is represented using a line corresponding to the travel route included in the actual travel data and a circle including the travel route.

The travelable range may be represented by at least one method, and the method is not limited to a circle or a line along a travel route (i.e., road). The travelable range may be represented by, for example, a shape including the travel route along the topography of the area or a shape including the travel route in contact therewith. For example, the travelable range may be represented using a series of dots indicating a stop point.

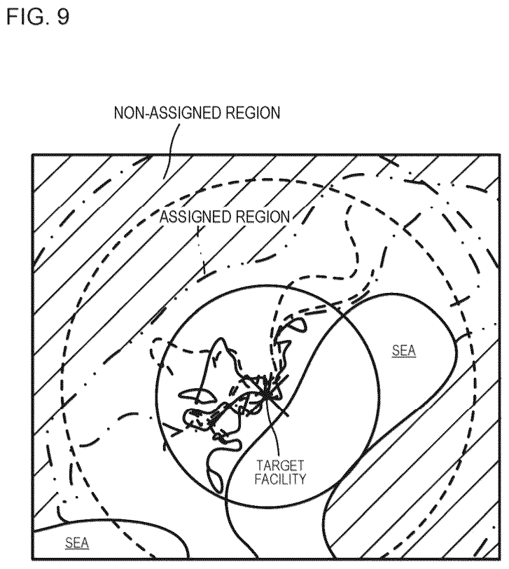

FIG. 9 is a diagram illustrating a display example of a travelable range according to a plurality of stepwise criteria. Specifically, FIG. 9 corresponds to a diagram obtained by combining FIGS. 6 to 8, and is a diagram illustrating a display example of the travelable range according to the stepwise criteria in which the ratios of the remaining capacities are 50%, 27.5%, and 20%. FIG. 9 illustrates an example in which 50%, 27.5%, and 20% are illustrated in different display modes (solid line, dotted line, one-dot chain line) using different line types.

The display example of FIG. 9 includes a predetermined assigned region for the target facility. In FIG. 9, the assigned region is indicated by a two-dot chain line. Furthermore, in the display example of FIG. 9, hatching is used to indicate the non-assigned region.

In a case where the travelable range is estimated using each of the results of the plurality of simulations, the display control unit 106 may cause the display unit 105 to display the estimation results of the plurality of travelable ranges associated with the results of the plurality of simulations on separate screens. In this case, the display control unit 106 may cause the display unit 105 to display the estimation results of the plurality of travelable ranges associated with the results of the plurality of simulations on a plurality of appropriate screens. In this case, if there are regions (e.g., regions overlapping each other with predetermined stepwise criteria) overlapping each other in a plurality of travelable ranges, the overlapping region may be displayed on the display unit 105 in a mode (e.g., color is darkened) different from other regions.

The display control unit 106 may cause the display unit 105 to display a region outside the travelable range according to a predetermined stepwise criterion (e.g., ratio of remaining capacity is 27.5%), that is, a region outside the travelable range in a mode different from other regions using hatching or the like.

The display control unit 106 may cause the display unit 105 to display at least one of a point or a region where it is determined that battery depletion will occur by simulation, a point or a region where a gradient is equal to or more than a predetermined value in a case where a travel track record includes a gradient of a road on which the vehicle has traveled, and the like. At a point or a region where the gradient is equal to or more than a predetermined value, the power consumption of the second automobile using electricity as an energy source increases. Therefore, it is possible to easily visually recognize a point or a region where there is a high risk of battery depletion or an accident.

### Operation and Effect

As described above, according to the present example embodiment, the information processing device 100 includes the simulation unit 103 and the range estimation unit 104.

The simulation unit 103 uses actual travel data of a first automobile using fuel as an energy source, which is associated with a target facility, to perform a simulation regarding electricity consumed in a case where the second automobile using electricity as an energy source travels according to the actual travel data.

Using the result of the simulation, the range estimation unit 104 estimates a travelable range according to a plurality of stepwise criteria regarding a battery depletion risk.

As a result, in a case where the second automobile using electricity as an energy source is used instead of the first automobile using fuel as an energy source, the relationship between the battery depletion risk and the travelable range of the second automobile can be estimated according to the actual traveling. Therefore, it is possible to accurately estimate a travelable range of an automobile using electricity as an energy source.

According to the present example embodiment, the information processing device 100 further includes the display control unit 106 that causes the display unit 105 to display the travelable range according to at least one stepwise criterion on the map displayed on the display unit 105. The display mode of the travelable range differs for each stepwise criterion.

As a result, the travelable range according to at least one stepwise criterion can be browsed on the map. Therefore, it is possible to consider introduction of the second automobile with reference to the travelable range according to the stepwise criterion and take necessary measures therefor.

According to the present example embodiment, the predetermined assigned region for the target facility is further displayed on the map.

As a result, the assigned region can be browsed on the map. Therefore, it is possible to consider introduction of the second automobile with reference to the assigned region and take necessary measures therefor.

According to the present example embodiment, the simulation is performed by further using model data related to electricity consumed by the second automobile in association with traveling.

As a result, in a case where the second automobile using electricity as an energy source is used instead of the first automobile using fuel as an energy source, the relationship between the battery depletion risk and the travelable range of the second automobile can be estimated according to the actual traveling. Therefore, it is possible to accurately estimate a travelable range of an automobile using electricity as an energy source.

### Second Example Embodiment

In the first example embodiment, an example in which there is one target facility has been described. However, there may be a plurality of target facilities. An information processing device according to the present example embodiment may include substantially the same components as those of the information processing device 100 according to the first example embodiment, both functionally and physically. Therefore, a functional configuration example of the information processing device according to the present example embodiment will be described with reference to FIG. 3.

An actual travel data acquisition unit 101 acquires actual travel data associated with each of a plurality of target facilities. The actual travel data acquisition unit 101 may acquire at least one piece of actual travel data for each of the plurality of target facilities. Each piece of the actual travel data may be similar to that of the first example embodiment.

A model data acquisition unit 102 may acquire model data similar to that of the first example embodiment.

Using each of the plurality of pieces of actual travel data acquired by the model data acquisition unit 102, a simulation unit 103 performs a simulation regarding power consumed in a case where the second automobile travels according to the actual travel data. That is, the simulation result may be generated for each of the plurality of pieces of actual travel data.

A range estimation unit 104 estimates a travelable range according to a plurality of stepwise criteria regarding the battery depletion risk using each of the results of the simulation performed by the simulation unit 103. For example, the range estimation unit 104 may estimate the travelable range for each of the plurality of target facilities.

As in the first example embodiment, a display control unit 106 causes a display unit 105 to display the travelable range and the like according to at least one stepwise criterion on a map displayed on the display unit 105.

For example, the display control unit 106 may cause the display unit 105 to display the travelable range for each of the plurality of target facilities on the map displayed on the display unit 105.

For example, the display control unit 106 may cause the display unit 105 to display a plurality of assigned regions determined in advance for the plurality of target facilities on the map displayed on the display unit 105. That is, the map displayed on the display unit 105 may include, for example, a plurality of assigned regions determined in advance for the plurality of target facilities.

Furthermore, for example, the display control unit 106 may cause the display unit 105 to display a non-assigned region in a mode different from the plurality of assigned regions. The non-assigned region is a region other than the plurality of assigned regions. In other words, the non-assigned region is a region not included in any of the plurality of assigned regions.

### Operation Example of Information Processing Device 100 According to Second Example Embodiment

Also in the present example embodiment, information processing may include substantially the same components as those of the information processing according to the first example embodiment. Therefore, the information processing according to the present example embodiment will be described with reference to FIG. 5.

The actual travel data acquisition unit 101 acquires actual travel data associated with each of a plurality of target facilities (step S101).

For example, the actual travel data acquisition unit 101 may acquire a plurality of pieces of actual travel data related to the first automobile associated with the plurality of target facilities. For example, the first automobiles of the facilities may be of the same vehicle type or of different vehicle types. As in the first example embodiment, the plurality of pieces of actual travel data may be, for example, a period between specified dates (e.g., one month), but is not limited thereto, and may be selected by an appropriate method.

The model data acquisition unit 102 acquires model data, for example, as in the first example embodiment (step S102).

Using each of the plurality of pieces of actual travel data acquired in step S101, the simulation unit 103 performs a simulation regarding electricity consumed in a case where the second automobile travels according to the actual travel data (step S103).

For example, as in the first example embodiment, the simulation unit 103 may perform a simulation by further using the model data acquired in step S102.

Using the result of the simulation performed for each of the plurality of pieces of actual travel data in step S103, the range estimation unit 104 estimates a travelable range according to a plurality of stepwise criteria regarding a battery depletion risk (step S104).

For example, the range estimation unit 104 may estimate the travelable range for each of the plurality of target facilities.

As in the first example embodiment, the display control unit 106 causes the display unit 105 to display the travelable range and the like according to at least one stepwise criterion on the map displayed on the display unit 105.

For example, the display control unit 106 may cause the display unit 105 to display the travelable range estimated for some or all of the plurality of target facilities on the map displayed on the display unit 105. At this time, the display control unit 106 may cause the display unit 105 to display the travelable range in a different display mode for each target facility so that each of the plurality of target facilities can be distinguished and recognized.

For example, the display control unit 106 may cause the display unit 105 to display a plurality of assigned regions determined in advance for the plurality of target facilities on the map displayed on the display unit 105.

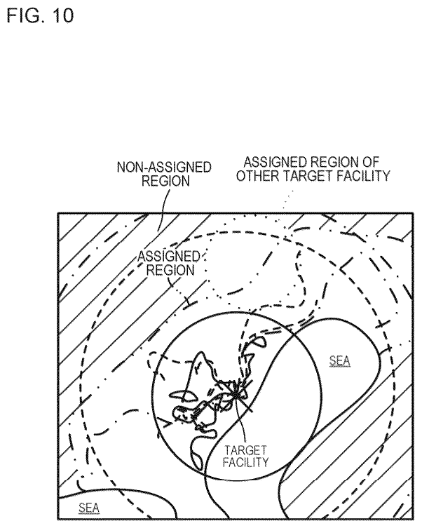

FIG. 10 is a diagram illustrating a display example of a plurality of assigned regions. In FIG. 10, the assigned region is indicated by a two-dot chain line and a dotted line. FIG. 10 includes the same travelable range as FIG. 9 for the target facility illustrated in FIG. 9. Furthermore, in the display example of FIG. 10, hatching is used to indicate the non-assigned region. The display control unit 106 may cause the display unit 105 to display the travelable range estimated for each of the plurality of assigned facilities on the map displayed on the display unit 105.

### Operation and Effect

As described above, according to the present example embodiment, there are a plurality of target facilities. A plurality of assigned regions determined in advance for the plurality of target facilities are displayed on the map. Displaying the plurality of assigned regions includes displaying the non-assigned region, which is a region other than the plurality of assigned regions, in a mode different from that of the plurality of assigned regions.

As a result, it is possible to emphasize the display of the non-assigned region. Therefore, it is possible to easily identify the non-assigned region and easily recognize the region in which measures (e.g., arrangement of charging facility or the like) for conducting a business using the second automobile are required.

According to the present example embodiment, the travelable range estimated for at least one target facility among the plurality of target facilities is further displayed on the map.

As a result, the relationship between the travelable range related to at least one target facility and an assigned region of another target facility can be easily visually recognized on the map. Therefore, it is possible to consider the introduction of the second automobile in consideration of the cooperation of the plurality of target facilities and take necessary measures therefor.

While the example embodiments and modifications of the present invention have been described above with reference to the drawings, these are examples of the present invention, and various configurations other than the above can be adopted.

In the plurality of flowcharts used in the above description, a plurality of steps (processing) is described in order, but the execution order of the steps executed in each example embodiment is not limited to the described order. In each example embodiment, the order of the illustrated steps can be changed as long as there is no problem in terms of content. The above-described example embodiments and modifications can be combined within a range in which the contents are not contradictory.

Furthermore, in the present disclosure, for example, a program that causes one or more computers to function as the information processing device 100 described in the above example embodiments or causes one or more computers to execute information processing, a recording medium in which the program is recorded, or the like may be provided.

Some or all of the example embodiments described above may be described as the following supplementary notes, but are not limited to the following.
1.

An information processing device including
a simulation means for using actual travel data of a first automobile using fuel as an energy source to perform a simulation regarding electricity consumed in a case where a second automobile using electricity as an energy source travels according to the actual travel data, the actual travel data being associated with a target facility, and
a range estimation means for estimating a travelable range according to a plurality of stepwise criteria regarding a battery depletion risk using a result of the simulation.
2.

The information processing device according to 1, further including
a display control means for causing a display means to display a travelable range according to at least one of the stepwise criteria on a map displayed on the display means, in which
a display mode of the travelable range is different for each of the stepwise criteria.
3.

The information processing device according to 2, in which
a predetermined assigned region for the target facility is further displayed on the map.
4.

The information processing device according to 3, in which:
there are a plurality of the target facilities;
a plurality of the assigned regions determined in advance for the plurality of target facilities are displayed on the map; and
displaying the plurality of assigned regions includes displaying a non-assigned region that is a region other than the plurality of assigned regions in a mode different from the plurality of assigned regions.
5.

The information processing device according to 4, in which
a travelable range estimated for at least one target facility among the plurality of target facilities is further displayed on the map.
6.

The information processing device according to any one of 1 to 5, in which
the simulation is performed by further using model data related to electricity consumed by the second automobile in association with traveling.
7.

An information processing method including
one or more computers
using actual travel data of a first automobile using fuel as an energy source to perform a simulation regarding electricity consumed in a case where a second automobile using electricity as an energy source travels according to the actual travel data, the actual travel data being associated with a target facility, and
estimating a travelable range according to a plurality of stepwise criteria regarding a battery depletion risk using a result of the simulation.
8.

The information processing method according to 7, further including
causing a display means to display a travelable range according to at least one of the stepwise criteria on a map displayed on the display means, in which
a display mode of the travelable range is different for each of the stepwise criteria.
9.

The information processing method according to 8, in which
a predetermined assigned region for the target facility is further displayed on the map.
10.

The information processing method according to 9, in which:
there are a plurality of the target facilities;
a plurality of the assigned regions determined in advance for the plurality of target facilities are displayed on the map; and
displaying the plurality of assigned regions includes displaying a non-assigned region that is a region other than the plurality of assigned regions in a mode different from the plurality of assigned regions.
11.

The information processing method according to 10, in which
a travelable range estimated for at least one target facility among the plurality of target facilities is further displayed on the map.
12.

The information processing method according to any one of 7 to 11, in which
the simulation is performed by further using model data related to electricity consumed by the second automobile in association with traveling.
13.

A recording medium recording a program for causing one or more computers to
use actual travel data of a first automobile using fuel as an energy source to perform a simulation regarding electricity consumed in a case where a second automobile using electricity as an energy source travels according to the actual travel data, the actual travel data being associated with a target facility, and
estimate a travelable range according to a plurality of stepwise criteria regarding a battery depletion risk using a result of the simulation.
14.

The recording medium recording a program according to 13, further causing a display means to display a travelable range according to at least one of the stepwise criteria on a map displayed on the display means, in which
a display mode of the travelable range is different for each of the stepwise criteria.
15.

The recording medium recording a program according to 14, in which
a predetermined assigned region for the target facility is further displayed on the map.
16.

The recording medium recording a program according to 15, in which:
there are a plurality of the target facilities;
a plurality of the assigned regions determined in advance for the plurality of target facilities are displayed on the map; and
displaying the plurality of assigned regions includes displaying a non-assigned region that is a region other than the plurality of assigned regions in a mode different from the plurality of assigned regions.
17.

The recording medium recording a program according to 16, in which
a travelable range estimated for at least one target facility among the plurality of target facilities is further displayed on the map.
18.

The recording medium recording a program according to any one of 13 to 17, in which
the simulation is performed by further using model data related to electricity consumed by the second automobile in association with traveling.
19.

A program for causing one or more computers to
use actual travel data of a first automobile using fuel as an energy source to perform a simulation regarding electricity consumed in a case where a second automobile using electricity as an energy source travels according to the actual travel data, the actual travel data being associated with a target facility, and
estimate a travelable range according to a plurality of stepwise criteria regarding a battery depletion risk using a result of the simulation.
20.

The program according to 19, further causing a display means to display a travelable range according to at least one of the stepwise criteria on a map displayed on the display means, in which
a display mode of the travelable range is different for each of the stepwise criteria.
21.

The program according to 20, in which
a predetermined assigned region for the target facility is further displayed on the map.
22.

The program according to 21, in which:
there are a plurality of the target facilities;
a plurality of the assigned regions determined in advance for the plurality of target facilities are displayed on the map; and
displaying the plurality of assigned regions includes displaying a non-assigned region that is a region other than the plurality of assigned regions in a mode different from the plurality of assigned regions.
23.

The program according to 22, in which
a travelable range estimated for at least one target facility among the plurality of target facilities is further displayed on the map.
24.

The program according to any one of 19 to 23, in which
the simulation is performed by further using model data related to electricity consumed by the second automobile in association with traveling.

### Reference Signs List

100 information processing device
101 actual travel data acquisition unit
102 model data acquisition unit
103 simulation unit
104 range estimation unit
105 display unit
106 display control unit

What is claimed is:

1. An information processing apparatus comprising:
a memory configured to store instructions; and
a processor configured to execute the instructions to:
use actual travel data of a first automobile using fuel as an energy source to perform a simulation regarding electricity consumed in a case where a second automobile using electricity as an energy source travels according to the actual travel data, the actual travel data being associated with a target facility; and
estimate a travelable range according to a plurality of stepwise criteria regarding a battery depletion risk using a result of the simulation.

2. The information processing apparatus according to claim 1, wherein
the processor configured to execute further instructions to:
a cause a display to display a travelable range according to at least one of the stepwise criteria on a map displayed on the display, wherein
a display mode of the travelable range is different for each of the stepwise criteria.

3. The information processing apparatus according to claim 2, wherein
a predetermined assigned region for the target facility is further displayed on the map.

4. The information processing apparatus according to claim 3, wherein:
there are a plurality of the target facilities;
a plurality of the assigned regions determined in advance for the plurality of target facilities are displayed on the map; and
displaying the plurality of assigned regions includes displaying a non-assigned region that is a region other than the plurality of assigned regions in a mode different from the plurality of assigned regions.

5. The information processing apparatus according to claim 4, wherein
a travelable range estimated for at least one target facility among the plurality of target facilities is further displayed on the map.

6. The information processing apparatus according to claim 1, wherein
the simulation is performed by further using model data related to electricity consumed by the second automobile in association with traveling.

7. An information processing method comprising:
one or more computers
using actual travel data of a first automobile using fuel as an energy source to perform a simulation regarding electricity consumed in a case where a second automobile using electricity as an energy source travels according to the actual travel data, the actual travel data being associated with a target facility; and
estimating a travelable range according to a plurality of stepwise criteria regarding a battery depletion risk using a result of the simulation.

8. A non-transitory computer readable medium recording a program for causing one or more computers to:
use actual travel data of a first automobile using fuel as an energy source to perform a simulation regarding electricity consumed in a case where a second automobile using electricity as an energy source travels according to the actual travel data, the actual travel data being associated with a target facility; and
estimate a travelable range according to a plurality of stepwise criteria regarding a battery depletion risk using a result of the simulation.
